(19) United States
(12) Patent Application Publication
(10) Pub. No.: US 2026/0114243 A1
(43) Pub. Date: Apr. 23, 2026

(54) MOLECULAR LAYER INFILTRATION OF PHOTORESISTS

(71) Applicant: Tokyo Electron Limited, Tokyo (JP)

(72) Inventor: Kandabara Tapily, Albany, NY (US)

(21) Appl. No.: 18/919,090

(22) Filed: Oct. 17, 2024

(51) Int. Cl. H01L 21/033; G03F 7/00; G03F 7/20

(52) U.S. Cl. CPC H10P 76/4085; G03F 7/2004; G03F 7/70033

(57) ABSTRACT

A method for forming a semiconductor device can include forming a first photoresist layer of a first photoresist material on a substrate, performing molecular layer infiltration (MLI) of the first photoresist layer to form a first MLI photoresist layer of a first MLI photoresist material such that the first MLI photoresist material chemically differs from the first photoresist material, forming a second photoresist layer of a second photoresist material on the first MLI photoresist layer, where the second photoresist material differs from the first MLI photoresist material, performing MLI of the second photoresist layer to form a second MLI photoresist layer of a second MLI photoresist material such that the second MLI photoresist material chemically differs from the second photoresist material, and patterning the second MLI photoresist layer and the first MLI photoresist layer using light of a specific waveform, such as extreme ultraviolet light.

### TECHNICAL FIELD

The present disclosure relates generally to methods for manufacturing semiconductor devices, and more particularly, molecular layer infiltration of photoresists in methods for manufacturing semiconductor devices.

### BACKGROUND

As semiconductor manufacturing progresses to smaller technology nodes (e.g., 5 nm, 3 nm, and beyond), the control of line edge roughness (LER) and line width roughness (LWR) becomes even more critical. A high degree of roughness in a patterned photoresist material can create variations and flaws that can lead to performance variations, increased power consumption, or even defects in the semiconductor devices. Improving lithographic techniques, resist materials, and post-lithography processes can minimize LER and LWR.

The use of extreme ultraviolet (EUV) lithography (e.g., 13.5 nanometers wavelength) and higher numerical aperture (NA) optical systems (e.g. for high NA EUV) are being used to improve the resolution and precision of patterning processes in semiconductor manufacturing. However, the use of EUV and high NA EUV presents new challenges for photolithography processes. One challenge is that EUV light generally does not penetrate into conventional photoresist material (e.g., organic photoresist material) as deeply as that of previously used deep ultraviolet (DUV) lithography and immersion lithography. Another challenge is that the light intensity while using EUV and high NA EUV is much lower than other prior-used photolithography techniques (e.g., DUV and immersion lithography) because the shorter wavelength of light for EUV results in lower photon energy density, which lowers the effective light intensity. And with many semiconductor fabrication facilities striving to use less overall energy, it is typically undesirable to increase the power used by an EUV tool for increasing light intensity.

Using EUV or high NA EUV to expose and pattern a single layer of conventional organic photoresist material is not providing sufficient resolution and precision due to LER and LWR issues for further progress to smaller technology nodes without significant increases in manufacturing costs (e.g., number of masks, number of processing steps, and energy usage). Thus, there is a need to improve photolithography techniques while making use of EUV and high NA EUV tools to enable further progress to smaller technology nodes while also constraining manufacturing costs.

### SUMMARY

In accordance with an embodiment of the present disclosure, a method for forming a semiconductor device can include: forming a first photoresist layer of a first photoresist material on a substrate; performing molecular layer infiltration (MLI) of the first photoresist layer to form a first MLI photoresist layer of a first MLI photoresist material such that the first MLI photoresist material chemically differs from the first photoresist material; forming a second photoresist layer of a second photoresist material on the first MLI photoresist layer, where the second photoresist material differs from the first MLI photoresist material; and patterning the second photoresist layer and the first MLI photoresist layer using light of a specific waveform.

In accordance with an embodiment of the present disclosure, a method for forming a semiconductor device can include: forming a first photoresist layer of a first photoresist material on a substrate; forming a second photoresist layer of a second photoresist material on the first photoresist layer; performing molecular layer infiltration (MLI) of the second photoresist layer to form a second MLI photoresist layer of a second MLI photoresist material such that the second MLI photoresist material chemically differs from the second photoresist material, and such that the second MLI photoresist material chemically differs from the first photoresist material; and patterning the second MLI photoresist layer and the first photoresist layer using light of a specific waveform.

In accordance with an embodiment of the present disclosure, a method for forming a semiconductor device can include: forming a first photoresist layer of a first photoresist material on a substrate; performing molecular layer infiltration (MLI) of the first photoresist layer to form a first MLI photoresist layer of a first MLI photoresist material such that the first MLI photoresist material chemically differs from the first photoresist material; forming a second photoresist layer of a second photoresist material on the first MLI photoresist layer, where the second photoresist material differs from the first MLI photoresist material; performing MLI of the second photoresist layer to form a second MLI photoresist layer of a second MLI photoresist material such that the second MLI photoresist material chemically differs from the second photoresist material; and patterning the second MLI photoresist layer and the first MLI photoresist layer using light of a specific waveform.

### BRIEF DESCRIPTION OF THE DRAWINGS

For a more complete understanding of example embodiments of the present disclosure, and the advantages thereof, reference is now made to the following descriptions taken in conjunction with the accompanying drawings, in which:

FIGS. 1A to 1F are cross-section views illustrating intermediate structures of photoresist layers made using a method according to an embodiment of the present disclosure;

FIG. 2 is a stack of two photoresist layers according to an embodiment of the present disclosure;

FIG. 3 is a stack of two photoresist layers according to an embodiment of the present disclosure;

FIG. 4 is a stack of two photoresist layers according to an embodiment of the present disclosure;

FIG. 5 is a stack of three photoresist layers according to an embodiment of the present disclosure;

FIG. 6 is a stack of three photoresist layers according to an embodiment of the present disclosure;

FIG. 7 is a stack of three photoresist layers according to an embodiment of the present disclosure;

FIG. 8 is a stack of three photoresist layers according to an embodiment of the present disclosure;

FIG. 9 is a stack of seven photoresist layers according to an embodiment of the present disclosure;

FIG. 10 is a stack of seven photoresist layers according to an embodiment of the present disclosure;

FIG. 11 is a flowchart illustrating a method of forming a stack of photoresist layers during a method for forming a semiconductor device according to an embodiment of the present disclosure;

FIG. 12 is a flowchart illustrating a method of forming a stack of photoresist layers during a method for forming a semiconductor device according to an embodiment of the present disclosure; and

FIG. 13 is a flowchart illustrating a method of forming a stack of photoresist layers during a method for forming a semiconductor device according to an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes, including relative thicknesses and/or widths of layers and structures shown in the drawings. One of ordinary skill in the art can appreciate many possible applications and variations for other embodiments based on the following illustrative and example embodiments provided in the present disclosure.

In the present disclosure, terms such as “first”, “second”, “third”, “fourth”, and the like, can be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments.

The current state of the art is using a single homogeneous layer of photoresist material, such as chemically amplified resist (CAR) or metal oxide resist (MOR), for EUV and/or high NA EUV lithography patterning during manufacturing of semiconductor devices. In some embodiments of the present disclosure, a method of forming a stack of photoresist layers during a method for forming a semiconductor device can include: forming a first photoresist layer of a first photoresist material on a substrate; performing molecular layer infiltration (MLI) of the first photoresist layer to form a first MLI photoresist layer of a first MLI photoresist material such that the first MLI photoresist material chemically differs from the first photoresist material; forming a second photoresist layer of a second photoresist material on the first MLI photoresist layer; optionally performing MLI of the second photoresist layer to form a second MLI photoresist layer of a second MLI photoresist material; and patterning the second MLI photoresist layer and the first MLI photoresist layer with EUV light using an EUV or high NA EUV tool.

Accordingly using some method embodiments of the present disclosure, the conversion of a given photoresist layer, or given photoresist layers, using MLI can alter absorption of and/or sensitivity to EUV so that the overall stack of photoresist layers can be tuned to provide improvements in LER and/or LWR, relative that which would be achieved using only one layer of non-MLI-treated photoresist material (e.g., conventional single layer of chemically amplified resist (CAR) or metal oxide resist (MOR)).

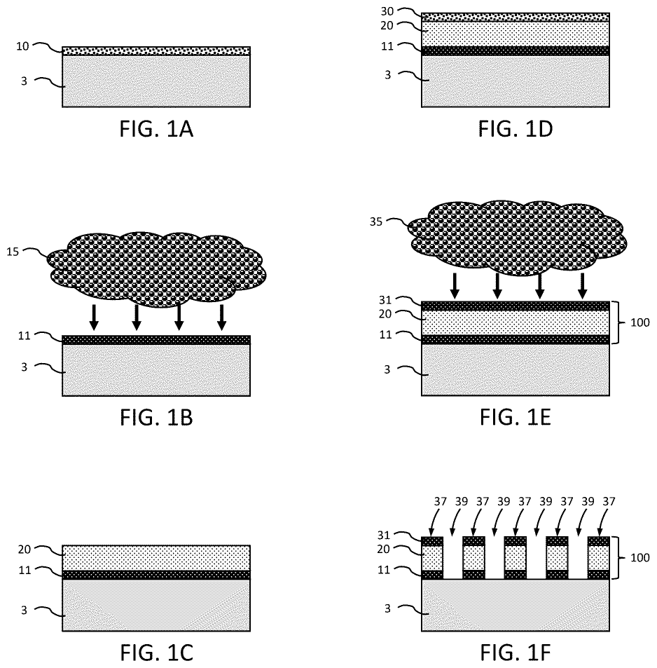

Some example embodiments of the present disclosure are described below with reference to FIGS. 1-13. Other embodiments can also be understood from the entirety of the specification as well as the claims herein.

Referring to FIGS. 1A to 10, a substrate 3 can be provided as an initial intermediate structure during the manufacturing of semiconductor devices. For simplification and illustration purposes, the substrate 3 is shown as a single layer with no details of what is therein. As can be readily understood by one of ordinary skill in the pertinent art, the substrate 3 can include multiple layers and/or multiple intermediate structures used in the manufacturing of semiconductor devices because an embodiment of the present disclosure can be applied and used at many different stages of the manufacturing of semiconductor devices (e.g., level Mo, M1, M2, M3, etc.).

For example, in FIGS. 1A to 10, to simplify the drawings, as can be readily understood by one of ordinary skill in the pertinent art, additional layers and structures of the substrate 3 for a semiconductor device made before, under, or below the intermediate structures shown in the drawings are not illustrated, which can include any structures, types, and semiconductor devices, such as additional layers used in a process of creating a pattern using photolithography techniques, such as additional layer(s) including (but not limited to) one or more photoresist layers, bottom anti-reflective coating (BARC), a barrier layer, an adhesion layer, a sacrificial layer, or such as one or more frontend-of-line (FEOL) stages or levels, transistors, diodes, capacitors, resistors, inductors, integrated circuits, memory cells, logic, processor portions, digital devices, analog devices, or such as interconnects, vias, trenches, one or more interlayer dielectric layers, one or more intermetal dielectric layers, one or more backend-of-line (BEOL) stages or levels, semiconductor wafer, or any combination thereof.

Also in FIGS. 1A to 10, to simplify the drawings, as can be readily understood by one of ordinary skill in the pertinent art, patterns, additional layers, and structures of intermediate structures for an overall manufacturing of semiconductor devices made after, over, or above the intermediate structures shown in the drawings are not illustrated, which can include any structures, types, and semiconductor devices, such as interconnects, vias, trenches, interlayer dielectric layers, intermetal dielectric layers, backend-of-line (BEOL) stage(s) or level(s), passivation layers, contact pads, local interconnects, global interconnects, wire bonding, packaging, or any combination thereof, for example.

Furthermore, in actual device cross-sections, the intermediate structures that are illustrated and represented in the drawings of the present disclosure in a simplified manner as having squared edges and/or linear shapes can be actually more rounded, more tapered, more curved shaped, and less linear shaped, and can be perhaps even difficult to visually see even in an image taken with a scanning electron microscope (SEM) or a transmission electron microscope (TEM) due the extremely small size, thickness, and scale of some layers and resulting features (e.g., some on a scale of less than 5 nanometers in size to a scale of atoms).

Initially while describing example process flows and example embodiments illustrated in FIGS. 1A to 13, the operations will be described generically in accordance with the example embodiments of the present disclosure without specifying particular materials, molecules infiltrated, and chamber conditions. Later in the present disclosure, some more detailed examples of particular materials, molecules infiltrated, and chamber conditions for process flow parameters, as well as some advantages and potential tuning options for an embodiment, will be described within contexts of the example embodiments described in FIGS. 1A to 13.

Referring to FIG. 1A, a first photoresist layer 10 of a first photoresist material can be formed on the substrate 3. The first photoresist layer 10 can be formed using any suitable technique, such as spin-on material deposition, atomic layer deposition (ALD), chemical vapor deposition (CVD), physical vapor deposition (PVD), or any combination thereof, and typically can be formed in a manner such that the layer has a substantially uniform thickness and composition across the wafer in a planar manner. The first photoresist layer 10 can be formed with a thickness up to 10 nanometers, for example. The first photoresist layer 10 can be formed with a thickness in a range of 2 nanometers to 3 nanometers, for example.

Referring to FIG. 1B, the wafer can be exposed to a vapor 15 containing molecules that can be infiltrated into and diffused into the first photoresist layer 10 to thereby chemically react and change the chemical composition of the first photoresist material of the first photoresist layer 10, while in a chamber configured or adapted for such operation, which can be referred to a molecular layer infiltration (MLI) in an MLI chamber. Accordingly, using MLI, the first photoresist material of the first photoresist layer 10 can be chemically altered to form a first MLI photoresist layer 11 of a first MLI photoresist material, such that after the MLI, the first MLI photoresist material chemically differs in composition from the first photoresist material. MLI can be considered similar to doping but plasma and ionization of molecules is not necessary. Instead, MLI can be a gaseous vapor based chemical reaction by diffusion of molecules into a photoresist material.

Referring to FIG. 1C, a second photoresist layer 20 of a second photoresist material can be formed on the first MLI photoresist layer 11. The second photoresist material of the second photoresist layer 20 can differ in chemical/material composition from the first MLI photoresist material of the first MLI photoresist layer 11, but not necessarily. Also, second photoresist material of the second photoresist layer 20 can differ in chemical/material composition from the first photoresist material of the first photoresist layer 10 that was previously formed on the substrate 3, but not necessarily. The second photoresist layer 20 can be formed using any suitable technique, such as spin-on material deposition, atomic layer deposition (ALD), chemical vapor deposition (CVD), physical vapor deposition (PVD), or any combination thereof, and typically can be formed in a manner such that the layer has a substantially uniform thickness and composition across the wafer in a planar manner. The second photoresist layer 20 can be formed with a thickness up to 10 nanometers, for example. The second photoresist layer 20 can be formed with a thickness in a range of 2 nanometers to 3 nanometers, for example.

Because the second photoresist material of the second photoresist layer 20 is not converted using MLI in this example embodiment, the second photoresist layer 20 can have a thickness greater than 10 nanometers. The thickness of the second photoresist layer 20 can depend upon many factors, such as the second photoresist material, the light intensity and light wavelength used for the photolithography patterning, feature sizes of the target pattern to be formed in the second photoresist material, the number of layers of photoresist materials, the thickness and materials of other layer(s) of photoresist material, or any combination thereof, for example.

Referring to FIG. 1D, a third photoresist layer 30 of a third photoresist material can be formed on the second photoresist layer 20. The third photoresist layer 30 can be formed using any suitable technique, such as spin-on material deposition, atomic layer deposition (ALD), chemical vapor deposition (CVD), physical vapor deposition (PVD), or any combination thereof, and typically can be formed in a manner such that the layer has a substantially uniform thickness and composition across the wafer in a planar manner. The third photoresist layer 30 can be formed with a thickness up to 10 nanometers, for example. The third photoresist layer 30 can be formed with a thickness in a range of 2 nanometers to 3 nanometers, for example. The third photoresist material of the third photoresist layer 30 can differ in chemical/material composition from the second photoresist material of the second photoresist layer 20 and/or the first MLI photoresist material of the first MLI photoresist layer 11, but not necessarily. Also, third photoresist material of the third photoresist layer 30 can differ in chemical/material composition from the first photoresist material of the first photoresist layer 10 that was previously formed on the substrate 3, but not necessarily.

Referring to FIG. 1E, the wafer can be exposed to a vapor 35 containing molecules that can be infiltrated into and diffused into the third photoresist layer 30 to thereby chemically react and change the chemical composition of the third photoresist material of the third photoresist layer 30, while in a chamber configured or adapted for such operation, which can be referred to as MLI in an MLI chamber. Accordingly, using MLI, the third photoresist material of the third photoresist layer 30 can be chemically altered to form a third MLI photoresist layer 31 of a third MLI photoresist material, such that after the MLI, the third MLI photoresist material chemically differs in composition from the third photoresist material. The third MLI photoresist material of the third MLI photoresist layer 31 can differ in chemical/material composition from the first MLI photoresist material of the first MLI photoresist layer 11, but not necessarily.

After the MLI operation illustrated in FIG. 1E, it results in a stack of photoresist layers including the first MLI photoresist layer 11, the second photoresist layer 20, and the third MLI photoresist layer 31, which together can be referred to as a stacked photoresist layer or a stacked resist layer 100. Accordingly, generally, while describing embodiments of the present disclosure herein, the term “stacked resist layer” can refer to a stack of multiple layers of photoresist material forming an overall “layer” including that stack of multiple layers. In a stacked resist layer of an embodiment, the layers can be layers of a same material or different materials. In an embodiment having the stacked resist layer 100 of FIG. 1E, the first MLI photoresist layer 11, the second photoresist layer 20, and the third MLI photoresist layer 31, can each have a same thickness, two of the three layers can have a same thickness, or each of the three layers can have different thicknesses relative to each other, for example.

Referring to FIG. 1F, after forming the stacked resist layer 100, the stacked resist layer 100 can be exposed and patterned using EUV light in an EUV or high NA EUV tool, for example, and then developed with a developer to form mandrels 37 separated by holes 39.

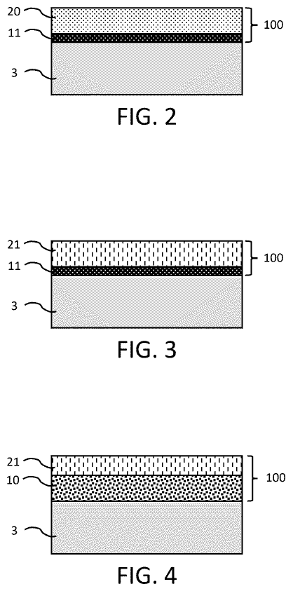

In an embodiment, the placement (e.g., lower level, mid level, upper level) and number of MLI-modified layers in a stacked resist layer can be varied and tuned to suit a given geometry node, given feature sizes and shapes, and given tool capabilities/limitations. FIGS. 2 to 10 show some other example embodiments to illustrate some potential variations of the placement, order, sequence, and use of MLI-modified layers or MLI-modified layers combined with non-MLI-modified layers in a stacked resist layer 100, according to some example applications of an embodiment of the present disclosure.

Referring to FIG. 2, a stacked resist layer 100 can include a first MLI photoresist layer 11 (e.g., same as or similar to the first MLI photoresist layer 11 described above relating to FIG. 1B) formed on a substrate 3, and a second photoresist layer 20 (e.g., same as or similar to the second photoresist layer 20 described above relating to FIG. 1C). The initial photoresist material deposited before converting such initial photoresist material to an MLI-modified photoresist material for the first MLI photoresist layer 11 and the second photoresist material of the second photoresist layer 20 can be a same photoresist material (e.g., CAR or MOR) or each can be different relative to each other. The first MLI photoresist layer 11 and the second photoresist layer 20 can each have a same thickness or they can have different thicknesses relative to each other. Hence, in an embodiment, a stacked resist layer can include just one MLI-modified photoresist layer and just one non-MLI-modified photoresist layer.

Referring to FIG. 3, a stacked resist layer 100 can include a first MLI photoresist layer 11 (e.g., same as or similar to the first MLI photoresist layer 11 described above relating to FIG. 1B) formed on a substrate 3, and a second MLI photoresist layer 21, where an MLI operation has been performed on a second photoresist layer of a second photoresist material to chemically convert and transform the second photoresist layer to the second MLI photoresist layer 21 (i.e., an MLI-modified photoresist layer). For example, the second MLI photoresist layer 21 can be formed in a same manner as described above regarding the first MLI photoresist layer 11 in FIG. 1B and/or the third MLI photoresist layer 31 in FIG. 1E.

Referring to FIG. 3, the first MLI photoresist layer 11 and the second MLI photoresist layer 21 can each have a same thickness or they can have different thicknesses relative to each other. The initial photoresist material deposited before converting such initial photoresist material to an MLI-modified photoresist material for the first MLI photoresist layer 11 and the second MLI photoresist layer 21 can be a same photoresist material (e.g., CAR or MOR) or each can be different relative to each other. Similarly, the resulting chemical composition of the first MLI photoresist layer 11 and the second MLI photoresist layer 21 can be a same photoresist material composition or each can be different relative to each other. As will be described more below, in most applications, the resulting chemical composition of the first MLI photoresist layer 11 and the second MLI photoresist layer 21 will be different relative to each other to provide advantages and benefits of a stacked resist layer according to an embodiment of the present disclosure. Hence, in an embodiment, a stacked resist layer can include just two MLI-modified photoresist layers.

Referring to FIG. 4, a stacked resist layer 100 can include a first photoresist layer 10 (e.g., same as or similar to the first photoresist layer 10 described above relating to FIG. 1A) formed on a substrate 3, and a second MLI photoresist layer 21 (e.g., same as or similar to the second MLI photoresist layer 21 described above relating to FIG. 3). The initial photoresist material deposited before converting such initial photoresist material to an MLI-modified photoresist material for the second MLI photoresist layer 21 and the first photoresist material of the first photoresist layer 10 can be a same photoresist material (e.g., CAR or MOR) or each can be different relative to each other. The first photoresist layer 10 and the second MLI photoresist layer 21 can each have a same thickness or they can have different thicknesses relative to each other. Hence, in an embodiment, a stacked resist layer can include just one MLI-modified photoresist layer and just one non-MLI-modified photoresist layer.

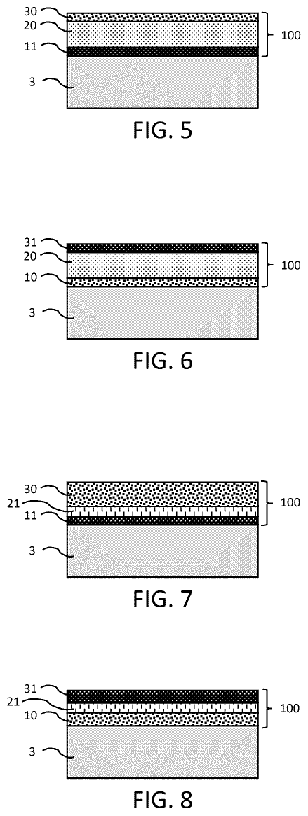

The example embodiments of FIGS. 5 and 6 can be variations upon the example embodiment of FIGS. 1A to 1F. Referring to FIG. 5, a stacked resist layer 100 can be formed using the operations described above for FIGS. 1A to 1D. Any two of or any combination of the initial photoresist material deposited before converting such initial photoresist material to an MLI-modified photoresist material for the first MLI photoresist layer 11, the second photoresist material of the second photoresist layer 20, and the third photoresist material of the third photoresist layer 30 can be a same photoresist material (e.g., CAR or MOR) or each can be different relative to each other. Any one of or any combination of the first MLI photoresist layer 11, the second photoresist layer 20, and the third photoresist layer 30 can each have a same thickness or they can have different thicknesses relative to each other.

Referring to FIG. 6, a stacked resist layer 100 can include a first photoresist layer 10 (e.g., same as or similar to the first photoresist layer 10 described above relating to FIG. 1A) formed on a substrate 3, a second photoresist layer 20 (e.g., same as or similar to the second photoresist layer 20 described above relating to FIG. 1C), and a third MLI photoresist layer 31 (e.g., same as or similar to the third MLI photoresist layer 31 described above relating to FIG. 1E). Any two of or any combination of the initial photoresist material deposited before converting such initial photoresist material to an MLI-modified photoresist material for the third MLI photoresist layer 31, the second photoresist material of the second photoresist layer 20, and the first photoresist material of the first photoresist layer 10 can be a same photoresist material (e.g., CAR or MOR) or each can be different relative to each other. Any one of or any combination of the first photoresist layer 10, the second photoresist layer 20, and the third MLI photoresist layer 31 can each have a same thickness or they can have different thicknesses relative to each other. Hence, in an embodiment, a stacked resist layer can include just one MLI-modified photoresist layer and two non-MLI-modified photoresist layers.

The example embodiments of FIGS. 7 and 8 can be additional variations upon the example embodiment of FIGS. 1A to 1F. Referring to FIG. 7, a stacked resist layer 100 can include a first MLI photoresist layer 11 (e.g., same as or similar to the first MLI photoresist layer 11 described above relating to FIG. 1B) formed on a substrate 3, a second MLI photoresist layer 21 (e.g., same as or similar to the second MLI photoresist layer 21 described above relating to FIG. 3), and a third photoresist layer 30 (e.g., same as or similar to the third photoresist layer 30 described above relating to FIG. 1D). Any two of or any combination of the initial photoresist material deposited before converting such initial photoresist material to an MLI-modified photoresist material for the first MLI photoresist layer 11 and/or the second MLI photoresist layer 21, and the third photoresist material of the third photoresist layer 30 can be a same photoresist material (e.g., CAR or MOR) or each can be different relative to each other. Any one of or any combination of the first MLI photoresist layer 11, the second MLI photoresist layer 21, and the third photoresist layer 30 can each have a same thickness or they can have different thicknesses relative to each other.

Referring to FIG. 8, a stacked resist layer 100 can include a first photoresist layer 10 (e.g., same as or similar to the first photoresist layer 10 described above relating to FIG. 1A) formed on a substrate 3, a second MLI photoresist layer 21 (e.g., same as or similar to the second MLI photoresist layer 21 described above relating to FIG. 3), and a third MLI photoresist layer 31 (e.g., same as or similar to the third MLI photoresist layer 31 described above relating to FIG. 1E). Any two of or any combination of the initial photoresist material deposited before converting such initial photoresist material to an MLI-modified photoresist material for the second MLI photoresist layer 21 and/or the third MLI photoresist layer 31, and the first photoresist material of the first photoresist layer 10 can be a same photoresist material (e.g., CAR or MOR) or each can be different relative to each other. Any one of or any combination of the first photoresist layer 10, the second MLI photoresist layer 21, and the third MLI photoresist layer 31 can each have a same thickness or they can have different thicknesses relative to each other. Hence, in an embodiment, a stacked resist layer can include two MLI-modified photoresist layers and just one non-MLI-modified photoresist layer.

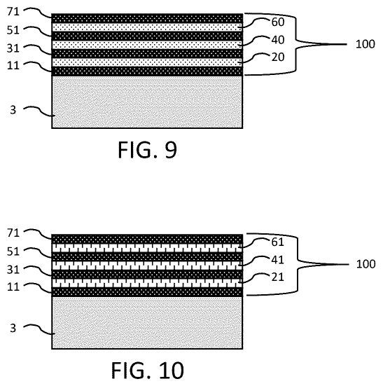

A stacked resist layer 100 of an embodiment can have any number of one or more MLI-modified layers combined with any number of zero or more non-MLI-modified layers, as illustrated in FIGS. 9 and 10 for example. Referring to FIG. 9, in an example embodiment of the present disclosure, a stacked resist layer 100 can include a group of MLI-modified photoresist layers alternating with a group of non-MLI-modified photoresist layers. More specifically, referring to FIG. 9, a stacked resist layer 100 can include a group of MLI-modified photoresist layers including a first MLI photoresist layer 11, a third MLI photoresist layer 31, a fifth MLI photoresist layer 51, and a seventh MLI photoresist layer 71. Still referring to FIG. 9, the stacked resist layer 100 can include a group of non-MLI-modified photoresist layers including a second photoresist layer 20, a fourth MLI photoresist layer 40, and a sixth photoresist layer 60.

Referring to FIG. 10, in an example embodiment of the present disclosure, a stacked resist layer 100 can include a group of MLI-modified photoresist layers and no non-MLI-modified photoresist layers. More specifically, referring to FIG. 10, a stacked resist layer 100 can include a group of only MLI-modified photoresist layers including a first MLI photoresist layer 11, a second MLI photoresist layer 21, a third MLI photoresist layer 31, a fourth MLI photoresist layer 41, a fifth MLI photoresist layer 51, a sixth MLI photoresist layer 61, and a seventh MLI photoresist layer 71.

In an embodiment of the present disclosure, by stacking layers of photoresist, the patterning profile can be tuned to improve the resolution and precision of the pattern by changing the absorption and sensitivity for different layers of the stacked resist layer 100. In an embodiment of the present disclosure, sensitivity and etch properties of a given layer of a stacked resist layer 100 can be selected and/or adjusted using MLI to provide a desired performance and characteristics of the stacked resist layer 100. In an embodiment of the present disclosure, a target can be to get to a more square/rectangular profile and reduce a required dose of EUV light. Increased sensitivity to EUV light can correlate with reducing or maintaining a dose requirement of EUV light for a given layer of the stacked resist layer 100. In an embodiment of the present disclosure, a target can be to tune the stacked resist layer 100 so that overall, the effective profile performance of the stacked resist layer 100 is that of a theoretically square/rectangular or more square/rectangular profile, for example. An embodiment of the present disclosure can give the ability and freedom to adjust and tune the resist stack with different material properties to get a desired pattern shape and/or profile for effectively providing greater resolution and precision by using a stacked resist layer 100. Thus, in an embodiment of the present disclosure, a designer can tune the profile of a patterned stacked resist layer based on the selection of layers and/or adjusting of one or more layers, using MLI, of the stacked resist layer 100.

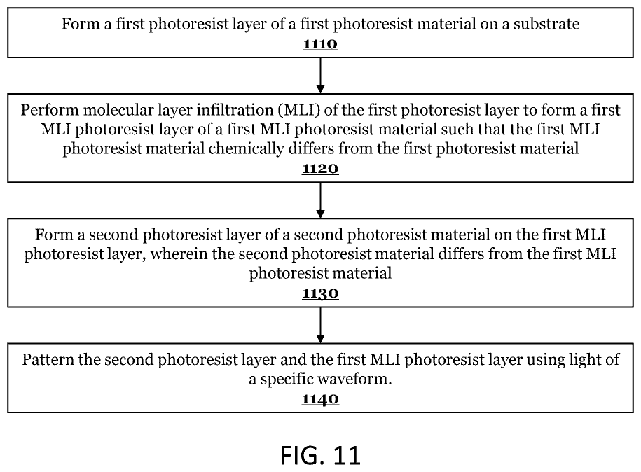

FIGS. 11 to 13 provide some example flowcharts illustrating some example methods that can be used for making the example embodiments described above and shown in FIGS. 1A to 10.

FIG. 11 is a flowchart illustrating a method of forming a stack of photoresist layers during a method for forming a semiconductor device according to an embodiment of the present disclosure. In a method of forming a stack of photoresist layers, the method can include forming a first photoresist layer of a first photoresist material on a substrate (box 1110). In a method of forming a stack of photoresist layers, the method can include performing molecular layer infiltration (MLI) of the first photoresist layer to form a first MLI photoresist layer of a first MLI photoresist material such that the first MLI photoresist material chemically differs from the first photoresist material (box 1120). In a method of forming a stack of photoresist layers, the method can include forming a second photoresist layer of a second photoresist material on the first MLI photoresist layer, where the second photoresist material differs from the first MLI photoresist material (box 1130). In a method of forming a stack of photoresist layers, the method can include patterning the second photoresist layer and the first MLI photoresist layer using light of a specific waveform (e.g., EUV light) (box 1140).

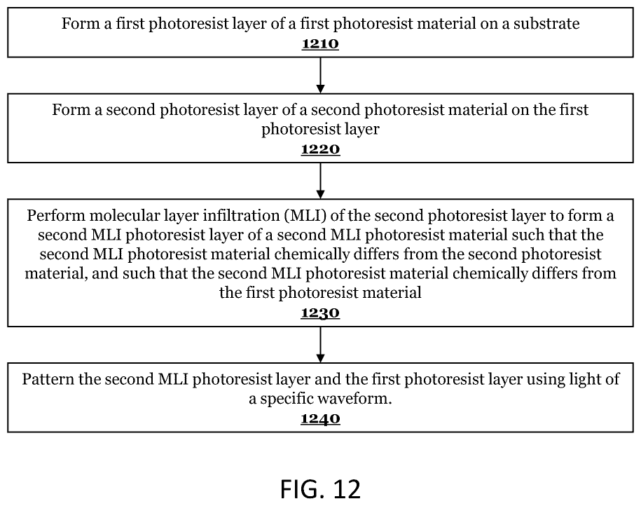

FIG. 12 is a flowchart illustrating a method of forming a stack of photoresist layers during a method for forming a semiconductor device according to an embodiment of the present disclosure. In a method of forming a stack of photoresist layers, the method can include forming a first photoresist layer of a first photoresist material on a substrate (box 1210). In a method of forming a stack of photoresist layers, the method can include forming a second photoresist layer of a second photoresist material on the first photoresist layer (box 1220). In a method of forming a stack of photoresist layers, the method can include performing molecular layer infiltration (MLI) of the second photoresist layer to form a second MLI photoresist layer of a second MLI photoresist material such that the second MLI photoresist material chemically differs from the second photoresist material, and such that the second MLI photoresist material chemically differs from the first photoresist material (box 1230). In a method of forming a stack of photoresist layers, the method can include patterning the second MLI photoresist layer and the first photoresist layer using light of a specific waveform (e.g., EUV light) (box 1240).

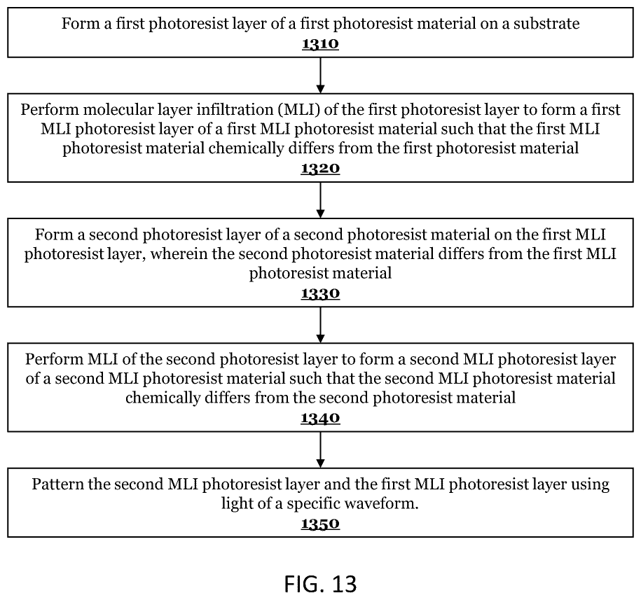

FIG. 13 is a flowchart illustrating a method of forming a stack of photoresist layers during a method for forming a semiconductor device according to an embodiment of the present disclosure. In a method of forming a stack of photoresist layers, the method can include forming a first photoresist layer of a first photoresist material on a substrate (box 1310). In a method of forming a stack of photoresist layers, the method can include performing molecular layer infiltration (MLI) of the first photoresist layer to form a first MLI photoresist layer of a first MLI photoresist material such that the first MLI photoresist material chemically differs from the first photoresist material (box 1320). In a method of forming a stack of photoresist layers, the method can include forming a second photoresist layer of a second photoresist material on the first MLI photoresist layer, where the second photoresist material differs from the first MLI photoresist material (box 1330). In a method of forming a stack of photoresist layers, the method can include performing MLI of the second photoresist layer to form a second MLI photoresist layer of a second MLI photoresist material such that the second MLI photoresist material chemically differs from the second photoresist material (box 1340). In a method of forming a stack of photoresist layers, the method can include patterning the second MLI photoresist layer and the first MLI photoresist layer using light of a specific waveform (e.g., EUV light) (box 1350).

Next, relating to the example embodiments described above and shown in FIGS. 1A to 13, as well as relating to other example embodiments and potential embodiments of the present disclosure, some detailed examples of particular materials, molecules infiltrated, and chamber conditions for process flow parameters will be described within contexts of the example embodiments described in FIGS. 1A to 13.

Generally, materials or molecules for an MLI operation in an embodiment can be organic or inorganic, and an initial photoresist material that will be converted to an MLI-modified photoresist layer can be organic or inorganic photoresist material. For example, an organic molecule can be used for MLI of an inorganic photoresist material. For example, an organic molecule can be used for MLI of an organic photoresist material. For example, an inorganic molecule can be used for MLI of an inorganic photoresist material. For example, an inorganic molecule can be used for MLI of an organic photoresist material. The combination for MLI molecule and photoresist material can be selected based on many factors while tuning and designing a stacked resist layer 100 for a given application, as will be further described next.

An advantage of using an embodiment of the present disclosure compared to a conventional single-layer-homogeneous-material photoresist layer is that each resulting material of each layer level of a stacked resist layer 100 can be selected, tuned, and designed such that the combination of resulting layers of the stacked resist layer 100 provides improvements for any of a wide variety of factors for a given application, including (but not necessarily limited to): increased/decreased sensitivity to EUV light for a certain layer or layers of the stacked resist layer 100 thereby improving the overall performance of the stacked resist layer 100; increased/decreased absorption of EUV light for a certain layer or layers of the stacked resist layer 100 thereby improving the overall performance of the stacked resist layer 100; improved effective patterning resolution (e.g., LER, LWR) for the stacked resist layer 100; improved control of a shape of the patterned stacked resist layer; improved effective patterning precision for the stacked resist layer 100; improved effective patterning profile through an entirety of the stacked resist layer 100; improved resist etch budget for the stacked resist layer 100; improved resist thermal budget for a certain layer or layers of the stacked resist layer 100 and/or for the overall stacked resist layer 100; increased mandrel or patterned structure rigidity/strength for the stacked resist layer 100 (e.g., to prevent/hinder a patterned stacked resist layer feature/mandrel/structure from leaning or falling over during subsequent operations relying on and using such feature/mandrel/structure); improved chemical stability after developing (e.g., during exposure to air and/or subsequent etching chemicals) for a certain layer or layers of the stacked resist layer 100 and/or for the overall stacked resist layer 100; improved moisture resistance for a certain layer or layers of the stacked resist layer 100 (e.g., top cap layer thereof) and/or for the overall stacked resist layer 100; improved hydrophilic properties for a certain layer or layers of the stacked resist layer 100 (e.g., top cap layer thereof) and/or for the overall stacked resist layer 100; improved hydrophobic properties for a certain layer or layers of the stacked resist layer 100 (e.g., top cap layer thereof) and/or for the overall stacked resist layer 100; improved etch selectivity for post lithography operations for a certain layer or layers of the stacked resist layer 100 (e.g., top layer thereof) and/or for the overall stacked resist layer 100; improved selectivity or non-selectivity for subsequent selective deposition of material relative to the patterned stacked resist layer for a certain layer or layers of the stacked resist layer 100 (e.g., top layer thereof) and/or for the overall stacked resist layer 100; or any combination thereof, for example. Some of these factors and advantages will be described in more detail below.

Certain photoresist materials have greater absorption and sensitivity to EUV light than other photoresist materials. For example, many inorganic photoresist materials, such as metal oxides, which can be included in MOR materials, have a larger absorption and sensitivity to EUV light than some conventionally used organic photoresist materials. Some example metal oxides that have relatively higher absorption and sensitivity to EUV light are aluminum oxide, tin oxide, antimony oxide, and indium oxide, for example. While certain metals, such as tin, antimony, and indium, have relatively higher absorption and sensitivity to EUV light, it can be challenging to use such metals as molecules alone for MLI because the metal can contaminate the chamber during MLI operations.

For using inorganic molecules for the MLI, there can be concern about metal contamination of the wafer or the tool chamber, which can bring more challenges. It can be more difficult to remove photoresist material that have been subjected to inorganic MLI and the developer chemistry may need to change compared to conventionally-used developers or commonly-used developers already currently in use and available in a given fabrication facility, which can bring more challenges. Excessive diffusion of metal molecules during MLI or after MLI can greatly affect thermal budget for the stacked resist layer 100. Subsequent processes while the stacked resist layer 100 is etched could potentially cause contamination by metal molecules previously inserted by MLI. Hence, certain molecules for MLI can present new challenges and/or problems. Thus, it can be easier and provide more advantages to use organic materials as molecules for the MLI operations in an embodiment for many applications.

In an example embodiment, the initial photoresist material deposited and that will be chemically converted using MLI can be a MOR material that includes but not limited to aluminum, tin, antimony, indium, hafnium, bismuth, or any combination thereof, for example. And when such MOR material is used, a polyamide material, such as Nylon (synthetic polymer), can be used for the molecules of the MLI operation to form the MLI-modified photoresist layer. Many polyamides will work well for molecules of an MLI operation because the molecules are not too bulky in size and can have high vapor pressure, which can allow such polyamides to penetrate well and diffuse well for an MLI operation.

A chamber used for performing an MLI operation can be referred to as an MLI chamber or MLI tool. For an example embodiment, in an MLI chamber, a polyamide material (e.g., Nylon) can be used as the molecules in a vapor for MLI into an MOR layer (e.g., containing tin oxide) having a thickness of less than 10 nanometers (e.g., 2-3 nanometers), within a pressure range of 1 mTorr to 10 Torr, and within a temperature range of 50° C. to 100° C., for example. For another example embodiment, in an MLI chamber, a polyamide material (e.g., Nylon) can be used as the molecules in a vapor for MLI into a CAR layer (e.g., CAR material conventionally used or already readily available in a fabrication facility) having a thickness of less than 10 nanometers (e.g., 2-3 nanometers), within a pressure range of 1 mTorr to 10 Torr, and within a temperature range of 50° C. to 100° C., for example. Using such materials and MLI chamber parameters in such example embodiments, the CAR layer and/or the MOR layer can be chemically converted to an MLI-modified photoresist layer that can have different chemical properties and different characteristics than the initial CAR/MOR layer, such as absorption of EUV light, sensitivity to EUV light, photoresist etch budget, temperature budget, or any combination thereof, for example.

Some polyamide materials can handle temperatures up to 400° C., depending on the material. However, for many polyamide materials that can be used for MLI of a photoresist material, the practical temperature limit can be less than 200° C. And even though a selected material used for providing the molecules of the MLI operation may be able to handle higher temperatures, a temperature limit for the initial photoresist material into which the MLI will occur and/or other layer(s) of photoresist material in the stacked resist layer 100 can be a limiting factor for a temperature limit for the MLI in the MLI chamber and/or for the thermal budget of the stacked resist layer 100.

In an MLI chamber during an MLI operation of an embodiment, the temperature and pressure of the vapor can be elevated to decrease the MLI time required, to aid in the diffusion of the molecules into the photoresist material, and to aid in the chemical reaction. However, the temperature and pressure of the vapor in the MLI chamber typically should not be too high because most organic materials and/or photoresist materials do not have a high temperature budget. Also, too high on temperature and pressure could modify the chemical properties of the photoresist resist in an undesired way, such as reducing EUV sensitivity when trying to increase EUV sensitivity. So, a goal can be to flow the MLI material/molecules into the MLI chamber in a gaseous vapor phase with some elevated temperature and pressure, enough to accelerate the chemical reaction and to push the molecules of the MLI into the photoresist material, but not too much. The molecules of MLI can diffuse into the photoresist material by a chemical reaction over a period of time. After the MLI operation, the material composition of the photoresist material can be changed.

One of the challenges/problems of patterning using EUV light on a single homogeneous layer of resist (e.g., MOR, metal oxide) is that the pattern profile can be tapered (i.e., upper portion wider and lower portion narrower for features) instead of a vertical/rectangular profile. The upper portions of the resist can absorb most of the EUV light because the metal oxide has a high absorption for EUV light. And then, because the upper portion absorbs most of the EUV light, the bottom portion can get very little dose or exposure of EUV light. As the surface absorbs the photons, the surface can densify and limit the further penetration of EUV light through that surface. One way to mitigate that issue is to have a smaller resist thickness. But then the resist thickness may not be enough to remain for etching and transferring the pattern into the underlying substrate, which can be referred to as the resist etch budget. So, if the resist is too thin, there may not be enough resist etch budget to complete the etch of the pattern into the substrate using the patterned resist layer. And if the resist is too thick, the resist can have a tapered profile or too much tapering, which can affect the precision and consistency of the pattern.

Another option to resolve these problems that can be encountered when using a single homogeneous layer of resist can be to increase EUV power (i.e., increase EUV light intensity). However, because many manufacturers are under cost and environment pressures to reduce power consumption for a semiconductor fabrication facility, a process flow designer or EUV tool operator may not be permitted to increase the EUV power or it may be undesired to increase the EUV power. This has led to use of metal oxide for resist (MOR materials) for EUV or high NA EUV patterning using EUV light because MOR material can provide higher absorption than conventional organic resist materials. However, using a single homogeneous layer of MOR material is often not sufficient for providing a high resolution and non-tapered patterned structure because the resist layer is too thick and/or for providing sufficient resist etch budget because the resist layer is too thin. An embodiment of the present disclosure with a stacked resist layer 100 can solve these problems and challenges of using EUV light for photolithography by providing a better balance between patterned structure precision/resolution (e.g., LER, LWR), less tapered structures, and sufficient resist etch budget, for example.

For example, in an embodiment of the present disclosure, deposited photoresist materials and/or resulting photoresist materials from MLI operation(s) of an upper layer or upper layers of a stacked resist layer 100 can be selected to have less absorption and less sensitivity to EUV light compared to a lower layer or lower layers of the stacked resist layer 100. For example, in an embodiment of the present disclosure, deposited photoresist materials and/or resulting photoresist materials from MLI operation(s) of a lower layer or lower layers of a stacked resist layer 100 can be selected to have greater absorption and greater sensitivity to EUV light compared to an upper layer or upper layers of the stacked resist layer 100. Using either or both of such selections when designing and tuning a stacked resist layer 100 can enable the lower layer or lower layers of the stacked resist layer 100 to be sufficiently exposed for a given dosage (power, light intensity, exposure time) of EUV light in an EUV patterning tool/operation relative to the upper layer or upper layers of the stacked resist layer 100, which can result in an improved overall exposure uniformity through most of or an entire depth of the stacked resist layer 100.

For an upper layer or upper layers of a stacked resist layer 100 of an embodiment, a designer may want lower absorption and lower sensitivity of EUV light. And for a lower layer or lower layers of a stacked resist layer 100 of an embodiment, a designer may want higher absorption and higher sensitivity of EUV light. An advantage of an embodiment of the present disclosure is that MLI can affect a given resist layer in either direction (i.e., increasing or decreasing absorption/sensitivity to EUV light). Thus, in some embodiments, one of, both of, or some of the layers of the stacked resist layer 100 can be submitted to MLI to tune the overall stacked resist layer 100 as needed or as desired for a given application. For example, the precision/resolution and/or resist etch budget can be quite different for patterning a stacked resist layer 100 for an M0 or M1 level of a semiconductor device, as compared that of an M2 or higher level of a semiconductor device, and thus, a stacked resist layer 100 of an embodiment can be tuned accordingly to provide an optimum or preferred balance between precision/resolution and resist etch budget. For example, if etching M0 or M1 level with a much higher pitch, as compared to upper levels (M2 and above), then the resolution for the higher pitch can be more critical.

An embodiment of the present disclosure can have multiple layers of thin resist (e.g., 2-3 nanometers per layer) for the stacked resist layer 100. In an embodiment, a stacked resist layer 100 can have a top layer or upper layers with lower absorption for EUV light so the EUV light sufficiently reaches the lower/bottom layer(s).

In an embodiment, a stacked resist layer 100 can have a top layer having higher absorption for EUV light and make the bottom layer(s) having lower absorption for EUV light, but having the top layer changed so that it has a higher resist etch budget compared to the bottom layer(s). And thus, even with a thin overall stacked resist layer 100 (e.g., thin enough that the patterned profile uniformity is not tapered or less tapered), the etch selectivity or resistance provided by a top layer of the stacked resist layer 100 can greatly improve the resist etch budget for the overall stacked resist layer 100 compared to a conventional photoresist having just a single homogeneous layer of resist.

In an embodiment, a top photoresist layer that has been MLI-modified can effectively provide a cap layer to provide resistance to moisture for the stacked resist layer 100, for example.

For a given embodiment, the stack of layers selected for a stacked resist layer 100 can be tailored. For one target or application, it may be sufficient to have just two layers in the stacked resist layer 100, for example. And for another target or application, a stack of alternating layers may provide desired etch characteristics and effective profile, for example.

In some uses of an embodiment, thermal budget of the stacked resist layer 100 can be an important factor or consideration. Organic infiltration using MLI can provide improved thermal budget sometimes better than inorganic infiltration using MLI because with inorganic infiltration using metal there can be concerns about preventing or hindering unwanted metal diffusion. Because of problems with metal diffusion, inorganic infiltration using MLI can decrease thermal budget for a stacked resist layer 100. Whereas, organic infiltration using MLI can increase thermal budget and/or thermal stability for a stacked resist layer 100. Thus, using organic molecules for MLI in an embodiment can be preferred for many applications.

For an alternating stack of a stacked resist layer 100 of an embodiment (see, e.g., FIGS. 1F, 9, and 10), there can be a different roughness of the pattern for some layers than others, but the overall effective roughness by averaging the roughness over the profile can be better in total or for producing smoother etching of the substrate 3 (effectively) via the patterned stacked resist layer 100, as compared to if there was just one homogeneous layer of resist (as in a conventional resist layer). Also, the thickness of the stacked resist layer 100 and number of alternating layers in the stack can depend on the resist etch budget needed/desired to pattern the substrate 3 with the patterned stacked resist layer 100.

Because MLI can be self-limiting in terms of the depth into the photoresist material in which the molecules can diffuse (e.g., within a reasonable amount of time, within a reasonable thermal budget) and/or in terms of a saturation of the molecules to a certain depth subsequently limiting more infiltration of more molecules deeper into the photoresist material, the use multiple layers stacked can be implemented in an embodiment where uniformity of MLI-modification of a given layer is important for the design/tuning of the given layer and/or for the overall stacked resist layer 100. There can be a limit to the depth for which the MLI will diffuse. Once the surface is saturated and converted, lower portions of the layer may not be converted by the MLI process. Thus, by doing multiple layers of resist and multiple MLI operations, an embodiment can provide a more consistent formation of the layers of the stacked resist layer 100 and uniformity for conversion of the entire layer of resist for a given layer by the MLI for consistent control and results of the MLI operations. This can be another reason for having multiple stacked layers of resist when using the MLI process(es) for an embodiment of the present disclosure.

Depending on the molecule used to infiltrate the photoresist material for a given MLI operation in an embodiment, different molecules can have different infiltration depths that are possible within given temperature and pressure parameters and for a given starting resist material. Thus, a thickness of a starting resist layer can be tuned to ensure that the MLI penetrates the entire depth of the starting resist layer, depending on the many factors, including the material of the starting resist layer, the molecule being infiltrated, the chamber conditions for MLI (temperature, pressure, flow rate), or any combination thereof, for example.

In an embodiment, by stacking, one already formed MLI layer can act as a barrier layer (e.g., due to self-limiting properties of MLI and/or due to differing materials per layer) for MLI penetrating through a subsequent MLI-modified layer to prevent penetration into the substrate 3 and/or into another resist layer. The prior formed MLI layer can act as a sort of barrier layer because it is already saturated, for example.

With the self-limiting property of MLI, a given resist layer can have a gradient, if desired, where the MLI penetrates to a certain depth while a lower portion of the same resist layer has less, very little, to no change from the MLI, creating a gradient within a given resist layer. This could be desirable for some applications. Thus, in some embodiments, the MLI of a given layer may uniformly penetrate and transform the entire resist layer. And in some embodiments, the MLI of a given layer may provide a gradient where upper portions of the resist layer are fully converted by the MLI, middle portions are partially converted by the MLI, and lower portions are not converted, for example.

Thus, the use of MLI processes and the use of multiple layers for a stacked resist layer 100 of an embodiment can give a lot of flexibility to design and tune a stacked resist layer 100 for a given application, which is an advantage of an embodiment of the present disclosure.

For selective MLI, in an embodiment, a designer may want to select an MLI molecule and resist material for a given layer, as well as making that given layer thin (e.g., 2-3 nanometers), so that the given MLI-modified layer acts as a barrier layer to prevent MLI of subsequent layers from penetrating into the substrate 3 and/or an underlying layer of resist, because it can be desirable to not alter and not change the substrate 3 and/or an underlying layer of resist by the MLI (i.e., to not contaminate the underlying layer). So, the MLI of the given layer can be selective to not infiltrating into the substrate, while subsequent MLI of subsequent layers can be not selective for MLI with respective to the substrate 3 and/or an underlying layer of resist such that the given MLI-modified photoresist layer can act as a sort of barrier layer for subsequent MLI operations of other subsequent photoresist layers.

For a selective MLI process, material of the resist layer subjected to MLI and/or the underlying material (of another lower layer of resist and/or the substrate) can be selected for a given molecule that will be used for the MLI process. There can be some organic materials that are more favorable for providing molecules for the MLI process. For example, a given molecule may have a high vapor pressure, but not all organic materials can handle or have a high vapor pressure. For effective MLI, it can be desirable to select certain molecules that can have high vapor pressure and/or higher thermal budget for temperature. For a selective MLI process, the choice of molecule can be selected based on the underlying material(s). Thus, any one of or any combination of the selection of molecule for the MLI, the selection of material of the underlying layer, and the selection of material for the resist layer being subjected to MLI, can vary in any combination thereof, for tuning the MLI process, which can provide flexibility in selections of materials. Sometimes, the selection of the molecule for infiltration can be limited by chemicals available in a given fab and/or compatibility with a given tool being used for the MLI process.

In some embodiments, it can be desirable to avoid the inserting a specific barrier layer (e.g., a non-photoresist layer) just for safeguarding the underlying layer from infiltration during an MLI process. Instead, selective MLI can be used to prevent, hinder, or reduce infiltration into the underlying layer based on the selection of materials/chemical/conditions for the MLI layer (i.e., the molecule for MLI and the starting resist layer that will be subjected to MLI). For example, selection of a molecule for use in MLI that is selective to going into and saturating the resist layer but not into (or much less into) the underlying layer, can be an application of selective MLI in the design of a process flow for a given embodiment of the present disclosure. The characteristics for the selective MLI layer that is placed to provide some barrier layer properties can also take into account the light absorption and effects on the overall patterning of the stacked resist layer 100.

In the selection and design of the stacked resist layers of a stacked resist layer 100 for an embodiment, implementing MLI processes for some or all of the stacked layers, can be a balance between number of layers, sensitivity of each given layer, and absorption of each given layer, because more layers added or used can cause more scattering of the light during the exposure operations for patterning the photoresist layers. Thus, use of an embodiment can involve a balance of many factors to tune the overall performance, characteristics, pattern results, and resist etch budget for a given stacked resist layer 100. A designer of a process flow can thus seek an optimum balance using a stacked resist layer 100 of an embodiment of the present disclosure.

Even though the cost of forming the stacked resist layer 100 of an embodiment can be more than the cost of forming a single homogeneous layer of resist material under conventional methods (e.g., because there can be more process steps/operations for forming the photoresist layer), in some embodiments, the use of the stacked resist layer 100 can enable a single mask/exposure operation to provide a desired pattern (at a desired resolution/precision and/or feature size) that would normally require multiple mask/exposure operations using a single homogeneous layer of resist per mask/exposure operation. And typically, the cost of each mask and use of an EUV exposure tool can be much greater than the cost of applying multiple layers of resist and doing MLI operation(s) to create a stacked resist layer 100 of an embodiment, for example. Thus, an embodiment can provide overall process flow cost effectiveness or perhaps even cost savings for progressing scaling to smaller geometry nodes using EUV and high NA EUV tools and process flows.

In some embodiments, the developer may need to be changed in view of the changes to the photoresist layers after MLI. In some embodiments, conventional developers and/or developers/chemicals already available in a given fab can be still used for the stacked resist layer 100, even where one or more MLI operations were performed. A stacked resist layer 100 of an embodiment can be compatible with conventional integration (using same developers). For some embodiments, a new/different developer can be implemented (even if not necessary) to improve a patterning of the stacked resist layer 100.

In some process integrations and process flows, homogeneity control and molecule cluster size control of a photoresist layer across the entirety of the wafer can be important. Typically, photoresist material is deposited using a spin on process. Thickness uniformity for the resist layer can become more important as geometry node size decreases. The molecular orientation of the photoresist can change depending on how the photoresist is deposited and/or depending on a thickness of the photoresist layer deposited. When the photoresist layer is thinner, the molecules can be better aligned, which can provide better homogeneity. As the resist layer is deposited more thickly, the molecule distribution can become less homogeneous across the wafer, even though the thickness is uniform across the wafer. At up to 10 nm thick, the homogeneity can be still sufficient, for example. But going greater than 10 nm can cause better/different molecule alignment near the center of the wafer compared to the edges of the wafer.

Having less homogeneity or variances of the molecular alignment across the wafer can cause different levels of EUV light absorption across the wafer. By making a stack of thin layers (each layer less than 10 nm), the homogeneity of the molecule alignments can be better controlled across the wafer to improve uniformity. Also, an MLI operation to modify a given photoresist layer can help elevate problems of homogeneity. Thus, a stacked resist layer 100 of an embodiment can provide advantages of homogeneity control and molecule cluster size control for photolithography process flows and integration.

Regarding improving or increasing resist etch budget, using some carbon for the MLI (e.g., organic molecules for MLI) can greatly increase the etch resistance of that layer. Thus, using carbon or a carbon containing molecule (organic) for MLI-modification of one or more layers of a stacked resist layer 100 can provide an overall increase of resist etch budget, which can be an advantage of using an embodiment of the present disclosure.

Area selective deposition (ASD) can be a selective deposition only into the pattern trenches or only on the tops of the patterned stacked resist layer, using a material that is selective to deposition on one material but not another. In some process integrations or process flows, it can be desired to make use of ASD of material on a stacked resist layer 100 of an embodiment to increase a thickness of the pattern structure to increase resist etch budget. Thus, using MLI to change the material composition of a top surface of the stacked resist layer 100 can be used to later provide ASD, which can help with increasing the resist etch budget by making the patterned resist height bigger, for example.

However, in an embodiment, using MLI for the top layer of the stacked resist layer 100 can provide a different etch property for the top surface using MLI without necessarily increasing the thickness (or less increase in thickness) because it can be a change of material properties using MLI rather than adding more material on top.

Selective deposition for ASD is typically surface driven (dependent on the chemical/material properties of the surface of a layer), such as based on having a material that is more prone to deposit one specific material onto another specific material. For example, oxides typically like to (are more prone to) deposit on an oxide surface. For example, if there is a top surface that is hydrophobic (hydrophobic material), using MLI, it can be possible to change that surface state from hydrophobic to hydrophilic, which could be useful for enabling selective deposition on that surface. Changing the chemical properties of a top surface of a stacked resist layer 100 can assist with or enable ASD on that top surface of the stacked resist layer 100 in a subsequent operation (e.g., after patterning the stacked resist layer 100), which can thereby increase a resist etch budget after the exposure and develop operations of patterning the stacked resist layer 100. Thus, a very thin top layer of the stacked resist layer 100 can be modified using MLI to form a very thin top surface of MLI modified resist in which the chemical properties of the top surface are changed. And because this can be limited to a very thin layer on the top surface of the stacked resist layer 100, it can provide the benefit of enabling ASD later while not significantly impacting the absorption and sensitivity of other resist layers under that top surface layer. Thus, the benefits of improving absorption and/or sensitivity for lower layers can be achieved while also getting the benefit of enabling ASD by changing the top surface of the stacked resist layer 100 using MLI in an embodiment of the present disclosure.

Or on the contrary, in some embodiments, a top surface of a stacked resist layer 100 can be modified using MLI so that the top surface of the stacked resist layer 100 inhibits, reduces, or hinders the deposition of certain materials onto the stacked resist layer 100 while such certain materials are being selectively deposited in areas other than the patterned stacked resist layer (e.g., into the holes/trenches between mandrels of the patterned stacked resist layer).

In some process flows for forming a mask using lithography, such as multiple patterning techniques (e.g., self-aligned double patterning, self-aligned quadruple patterning), there can be multiple sets of photoresist mandrels formed to achieve sub-lithography scale and patterning. In such process flows, there can be a thermal budget for subsequent stages/operations (e.g., baking) based on the resist materials from the earlier stages/operations (e.g., baking to form second mandrels after forming the first mandrels). In such process flows, using one or more MLI processes can alter and change the chemical properties of one or more resist layers of a stacked resist layer 100 in an embodiment, thereby improving or increasing the thermal budget of the earlier patterned stacked resist layer (e.g., used for the first mandrels), which can be another advantage of using an embodiment of the present disclosure.

An embodiment of the present disclosure can make use of MLI of a photoresist layer prior to the exposure and/or prior to develop to alter the chemical properties of the resist material(s) of a stacked resist layer 100, which can alter particular and/or overall characteristics and performance of the resist layer (i.e., the stacked resist layer 100) for photolithography (e.g., EUV light patterning).

More example embodiments of the present disclosure are summarized here. Other embodiments can also be understood from the entirety of the specification as well as the claims filed herein.

Example 1. A method for forming a semiconductor device, the method including: forming a first photoresist layer of a first photoresist material on a substrate; performing molecular layer infiltration (MLI) of the first photoresist layer to form a first MLI photoresist layer of a first MLI photoresist material such that the first MLI photoresist material chemically differs from the first photoresist material; forming a second photoresist layer of a second photoresist material on the first MLI photoresist layer, where the second photoresist material differs from the first MLI photoresist material; and patterning the second photoresist layer and the first MLI photoresist layer using light of a specific waveform.

Example 2. The method of example 1, where the second photoresist material differs from the first photoresist material.

Example 3. The method of one of examples 1 or 2, where the light of the specific waveform is extreme ultraviolet (EUV) at 13.5 nanometers.

Example 4. The method of one of examples 1 to 3, where the first photoresist material includes an inorganic material and where the performing MLI includes exposing the first photoresist layer to a first gaseous vapor containing an organic material in a reaction chamber.

Example 5. The method of one of examples 1 to 4, where the first photoresist layer has a first thickness of 10 nanometers or less, where the second photoresist layer has a second thickness of 10 nanometers or less, where the first photoresist material contains a metal oxide material, and where the performing MLI includes exposing the first photoresist layer to the first gaseous vapor containing a polyamide material in the reaction chamber at a temperature in a temperature range of 50° C. to 100° C. and at a pressure in a pressure range of 1 mTorr to 10 Torr.

Example 6. The method of one of examples 1 to 5, where one of or both of the first photoresist material and the second photoresist material contains a chemically amplified resist (CAR) material.

Example 7. The method of one of examples 1 to 6, where one of or both of the first photoresist material and the second photoresist material includes a metal oxide resist (MOR) material.

Example 8. The method of one of examples 1 to 7, where the MOR material contains a metal selected from the group consisting of hafnium, bismuth, aluminum, tin, antimony, and indium.

Example 9. The method of one of examples 1 to 8, further including: forming a third photoresist layer of a third photoresist material on the second photoresist layer; performing MLI of the third photoresist layer to form a third MLI photoresist layer of a third MLI photoresist material such that the third MLI photoresist material chemically differs from the third photoresist material, and such that the third MLI photoresist material differs from the second photoresist material; and during the patterning of the second photoresist layer and the first MLI photoresist layer, also patterning the third MLI photoresist layer using the light of the specific waveform.

Example 10. The method of one of examples 1 to 9, further including: forming a third photoresist layer of a third photoresist material on the second photoresist layer, where the third photoresist material differs from the second photoresist material, and where the third photoresist material differs from the first MLI photoresist material; and during the patterning of the second photoresist layer and the first MLI photoresist layer, also patterning the third photoresist layer using the light of the specific waveform.

Example 11. A method for forming a semiconductor device, the method including: forming a first photoresist layer of a first photoresist material on a substrate; forming a second photoresist layer of a second photoresist material on the first photoresist layer; performing molecular layer infiltration (MLI) of the second photoresist layer to form a second MLI photoresist layer of a second MLI photoresist material such that the second MLI photoresist material chemically differs from the second photoresist material, and such that the second MLI photoresist material chemically differs from the first photoresist material; and patterning the second MLI photoresist layer and the first photoresist layer using light of a specific waveform.

Example 12. The method of example 11, where the second photoresist material differs from the first photoresist material.

Example 13. The method of one of examples 11 or 12, further including: forming a third photoresist layer of a third photoresist material on the second MLI photoresist layer; performing MLI of the third photoresist layer to form a third MLI photoresist layer of a third MLI photoresist material such that the third MLI photoresist material chemically differs from the third photoresist material, and such that the third MLI photoresist material differs from the second MLI photoresist material; and during the patterning of the second MLI photoresist layer and the first photoresist layer, also patterning the third MLI photoresist layer using the light of the specific waveform.

Example 14. The method of one of examples 11 to 13, further including etch selectivity tuning by resist stack tuning, where the resist stack tuning includes the performing MLI of the second photoresist layer, such that a resist etch budget of the second MLI photoresist material is greater than the second photoresist material.

Example 15. The method of one of examples 11 to 14, where the patterning of the second MLI photoresist layer and the first photoresist layer forms a patterned stacked resist layer, and where the method further includes area selective depositing of a third layer on a top surface of the patterned stacked resist layer such that the third layer is selective to deposit on the second MLI photoresist layer relative to another material in an opened area of the patterned stacked resist layer.

Example 16. A method for forming a semiconductor device, the method including: forming a first photoresist layer of a first photoresist material on a substrate; performing molecular layer infiltration (MLI) of the first photoresist layer to form a first MLI photoresist layer of a first MLI photoresist material such that the first MLI photoresist material chemically differs from the first photoresist material; forming a second photoresist layer of a second photoresist material on the first MLI photoresist layer, where the second photoresist material differs from the first MLI photoresist material; performing MLI of the second photoresist layer to form a second MLI photoresist layer of a second MLI photoresist material such that the second MLI photoresist material chemically differs from the second photoresist material; and patterning the second MLI photoresist layer and the first MLI photoresist layer using light of a specific waveform.

Example 17. The method of example 16, further including: forming a third photoresist layer of a third photoresist material on the second MLI photoresist layer, where the third photoresist material differs from the second MLI photoresist material; and during the patterning of the second MLI photoresist layer and the first MLI photoresist layer, also patterning the third photoresist layer using the light of the specific waveform.

Example 18. The method of one of examples 16 or 17, further including: forming a third photoresist layer of a third photoresist material on the second MLI photoresist layer; performing MLI of the third photoresist layer to form a third MLI photoresist layer of a third MLI photoresist material such that the third MLI photoresist material chemically differs from the third photoresist material, and such that the third MLI photoresist material differs from the second MLI photoresist material; and during the patterning of the second MLI photoresist layer and the first MLI photoresist layer, also patterning the third MLI photoresist layer using the light of the specific waveform.

Example 19. The method of one of examples 16 to 18, further including: forming a fourth photoresist layer of a fourth photoresist material on the third MLI photoresist layer; performing MLI of the fourth photoresist layer to form a fourth MLI photoresist layer of a fourth MLI photoresist material such that the fourth MLI photoresist material chemically differs from the fourth photoresist material, and such that the fourth MLI photoresist material differs from the third MLI photoresist material; and during the patterning of the third MLI photoresist layer, the second MLI photoresist layer, and the first MLI photoresist layer, also patterning the fourth MLI photoresist layer using the light of the specific waveform.

Example 20. The method of one of examples 16 to 19, further including patterning a stacked resist layer to form a patterned stacked resist layer, where the stacked resist layer includes the second MLI photoresist layer and the first MLI photoresist layer, where the patterning of the stacked resist layer includes the patterning of the second MLI photoresist layer and the first MLI photoresist layer, where line edge roughness and line width roughness of the patterned stacked resist layer are improved compared to that of one of or both of the first photoresist layer and the second photoresist layer.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for forming a semiconductor device, the method comprising:
forming a first photoresist layer of a first photoresist material on a substrate;
performing molecular layer infiltration (MLI) of the first photoresist layer to form a first MLI photoresist layer of a first MLI photoresist material such that the first MLI photoresist material chemically differs from the first photoresist material;
forming a second photoresist layer of a second photoresist material on the first MLI photoresist layer, wherein the second photoresist material differs from the first MLI photoresist material; and
patterning the second photoresist layer and the first MLI photoresist layer using light of a specific waveform.

2. The method of claim 1, wherein the second photoresist material differs from the first photoresist material.

3. The method of claim 1, wherein the light of the specific waveform is extreme ultraviolet (EUV) at 13.5 nanometers.

4. The method of claim 1, wherein the first photoresist material comprises an inorganic material and wherein the performing MLI comprises exposing the first photoresist layer to a first gaseous vapor containing an organic material in a reaction chamber.

5. The method of claim 4, wherein the first photoresist layer has a first thickness of 10 nanometers or less, wherein the second photoresist layer has a second thickness of 10 nanometers or less, wherein the first photoresist material contains a metal oxide material, and wherein the performing MLI comprises exposing the first photoresist layer to the first gaseous vapor containing a polyamide material in the reaction chamber at a temperature in a temperature range of 50° C. to 100° C. and at a pressure in a pressure range of 1 mTorr to 10 Torr.

6. The method of claim 1, wherein one of or both of the first photoresist material and the second photoresist material contains a chemically amplified resist (CAR) material.

7. The method of claim 1, wherein one of or both of the first photoresist material and the second photoresist material comprises a metal oxide resist (MOR) material.

8. The method of claim 7, wherein the MOR material contains a metal selected from the group consisting of hafnium, bismuth, aluminum, tin, antimony, and indium.

9. The method of claim 1, further comprising:
forming a third photoresist layer of a third photoresist material on the second photoresist layer;
performing MLI of the third photoresist layer to form a third MLI photoresist layer of a third MLI photoresist material such that the third MLI photoresist material chemically differs from the third photoresist material, and such that the third MLI photoresist material differs from the second photoresist material; and
during the patterning of the second photoresist layer and the first MLI photoresist layer, also patterning the third MLI photoresist layer using the light of the specific waveform.

10. The method of claim 1, further comprising:
forming a third photoresist layer of a third photoresist material on the second photoresist layer, wherein the third photoresist material differs from the second photoresist material, and wherein the third photoresist material differs from the first MLI photoresist material; and
during the patterning of the second photoresist layer and the first MLI photoresist layer, also patterning the third photoresist layer using the light of the specific waveform.

11. A method for forming a semiconductor device, the method comprising:
forming a first photoresist layer of a first photoresist material on a substrate;
forming a second photoresist layer of a second photoresist material on the first photoresist layer;
performing molecular layer infiltration (MLI) of the second photoresist layer to form a second MLI photoresist layer of a second MLI photoresist material such that the second MLI photoresist material chemically differs from the second photoresist material, and such that the second MLI photoresist material chemically differs from the first photoresist material; and
patterning the second MLI photoresist layer and the first photoresist layer using light of a specific waveform.

12. The method of claim 11, wherein the second photoresist material differs from the first photoresist material.

13. The method of claim 11, further comprising:
forming a third photoresist layer of a third photoresist material on the second MLI photoresist layer;
performing MLI of the third photoresist layer to form a third MLI photoresist layer of a third MLI photoresist material such that the third MLI photoresist material chemically differs from the third photoresist material, and such that the third MLI photoresist material differs from the second MLI photoresist material; and
during the patterning of the second MLI photoresist layer and the first photoresist layer, also patterning the third MLI photoresist layer using the light of the specific waveform.

14. The method of claim 11, further comprising etch selectivity tuning by resist stack tuning, wherein the resist stack tuning includes the performing MLI of the second photoresist layer, such that a resist etch budget of the second MLI photoresist material is greater than the second photoresist material.

15. The method of claim 11, wherein the patterning of the second MLI photoresist layer and the first photoresist layer forms a patterned stacked resist layer, and wherein the method further comprises area selective depositing of a third layer on a top surface of the patterned stacked resist layer such that the third layer is selective to deposit on the second MLI photoresist layer relative to another material in an opened area of the patterned stacked resist layer.

16. A method for forming a semiconductor device, the method comprising:
forming a first photoresist layer of a first photoresist material on a substrate;
performing molecular layer infiltration (MLI) of the first photoresist layer to form a first MLI photoresist layer of a first MLI photoresist material such that the first MLI photoresist material chemically differs from the first photoresist material;
forming a second photoresist layer of a second photoresist material on the first MLI photoresist layer, wherein the second photoresist material differs from the first MLI photoresist material;
performing MLI of the second photoresist layer to form a second MLI photoresist layer of a second MLI photoresist material such that the second MLI photoresist material chemically differs from the second photoresist material; and
patterning the second MLI photoresist layer and the first MLI photoresist layer using light of a specific waveform.

17. The method of claim 16, further comprising:
forming a third photoresist layer of a third photoresist material on the second MLI photoresist layer, wherein the third photoresist material differs from the second MLI photoresist material; and
during the patterning of the second MLI photoresist layer and the first MLI photoresist layer, also patterning the third photoresist layer using the light of the specific waveform.

18. The method of claim 16, further comprising:
forming a third photoresist layer of a third photoresist material on the second MLI photoresist layer;
performing MLI of the third photoresist layer to form a third MLI photoresist layer of a third MLI photoresist material such that the third MLI photoresist material chemically differs from the third photoresist material, and such that the third MLI photoresist material differs from the second MLI photoresist material; and
during the patterning of the second MLI photoresist layer and the first MLI photoresist layer, also patterning the third MLI photoresist layer using the light of the specific waveform.

19. The method of claim 18, further comprising:
forming a fourth photoresist layer of a fourth photoresist material on the third MLI photoresist layer;
performing MLI of the fourth photoresist layer to form a fourth MLI photoresist layer of a fourth MLI photoresist material such that the fourth MLI photoresist material chemically differs from the fourth photoresist material, and such that the fourth MLI photoresist material differs from the third MLI photoresist material; and
during the patterning of the third MLI photoresist layer, the second MLI photoresist layer, and the first MLI photoresist layer, also patterning the fourth MLI photoresist layer using the light of the specific waveform.

20. The method of claim 16, further comprising patterning a stacked resist layer to form a patterned stacked resist layer, wherein the stacked resist layer includes the second MLI photoresist layer and the first MLI photoresist layer, wherein the patterning of the stacked resist layer includes the patterning of the second MLI photoresist layer and the first MLI photoresist layer, wherein line edge roughness and line width roughness of the patterned stacked resist layer are improved compared to that of one of or both of the first photoresist layer and the second photoresist layer.
